(19) United States
(12) Patent Application Publication
(10) Pub. No.: US 2021/0210706 A1
(43) Pub. Date: Jul. 8, 2021

(54) QUANTUM DOT AND MANUFACTURING METHOD THEREOF, QUANTUM DOT LIGHT EMITTING DIODE AND DISPLAY PANEL

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Gang YU, Beijing (CN); Aidi ZHANG, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 17/041,419

(22) PCT Filed: Mar. 11, 2020
(86) PCT No.: PCT/CN2020/078757

§ 371 Date: Sep. 24, 2020

(30) Foreign Application Priority Data
May 14, 2019 (CN) 201910396664.7

(51) Int. Cl. H01L 51/50; C09K 11/70; C09K 11/56

(52) U.S. Cl. CPC H01L 51/502; B82Y 20/00; C09K 11/565; C09K 11/70

(57) ABSTRACT

A quantum dot and a manufacturing method thereof, a quantum dot light emitting diode and a display panel are provided. The quantum dot includes: a quantum dot core, a charge transition layer coating at an outer side of the quantum dot core, and a quantum dot shell coating at an outer side of the charge transition layer. The charge transition layer includes a host material and metal ions doped in the host material, the metal ions are metal ions with variable charge valence states, and the charge valence states of the metal ions include a charge valence state of a cation in the quantum dot core and a charge valence state of a cation in the quantum dot shell.

The present application claims priority to Chinese patent application No. 201910396664.7 filed on May 14, 2019, and the entire disclosure of the aforementioned Chinese patent application is incorporated herein by reference as part of the present application.

### TECHNICAL FIELD

Embodiments of the present disclosure relates to a quantum dot and a manufacturing method thereof, a quantum dot light emitting diode and a display panel.

### BACKGROUND

As a new luminescent material, a quantum dot (QD) has the advantages of narrow luminescent spectrum, adjustable luminescent wavelength and high spectral purity, etc. A quantum dot light emitting diode (QLED) with quantum dot material as a light emitting layer has become a main research direction of novel display devices for the moment.

At present, the quantum dot is cadmium-system CdSe/CdS, that is, the quantum dot core and the quantum dot shell are formed by CdSe/CdS. However, CdSe/CdS contains toxic heavy metal cadmium, and cadmium-free system is the development trend of QD at present. At present, there is Auger recombination phenomenon between the interface of the quantum dot core and the interface of the quantum dot shell in the cadmium-free QD, which leads to more non-radiation transitions and weakens the luminescence ability of quantum dots.

### SUMMARY

At least one embodiment of the disclosure provides a quantum dot, comprising: a quantum dot core, a charge transition layer coating at an outer side of the quantum dot core, and a quantum dot shell coating at an outer side of the charge transition layer, wherein the charge transition layer comprises a host material and metal ions doped in the host material, wherein the metal ions are metal ions with variable charge valence states, and the charge valence states of the metal ions comprise a charge valence state of a cation in the quantum dot core and a charge valence state of a cation in the quantum dot shell.

In some examples, the metal ions are divalent/trivalent variable valence metal ions.

In some examples, the metal ions include at least one kind selected from the group consisting of manganese ions, iron ions, europium ions, cobalt ions and nickel ions.

In some examples, a thickness of the charge transition layer ranges from 1 to 10 atomic layers.

In some examples, a doping mass ratio of the metal ions to the host material of the charge transition layer is less than 5%.

In some examples, the host material of the charge transition layer is the same as a material of the quantum dot core, or the host material of the charge transition layer is the same as a material of at least a part of the quantum dot shell adjacent to the charge transition layer.

In some examples, a material of the quantum dot core is indium phosphide.

In some examples, the quantum dot shell comprises a first quantum dot shell coating the charge transition layer and a second quantum dot shell coating the first quantum dot shell; and a lattice mismatching between the first quantum dot shell and the quantum dot core is less than a lattice mismatching between the second quantum dot shell and the quantum dot core.

In some examples, a material of the first quantum dot shell is zinc selenide, and a material of the second quantum dot shell is zinc sulfide.

At least one embodiment of the disclosure provides a manufacturing method of a quantum dot, comprising: manufacturing a quantum dot core; forming a charge transition layer at an outer side of the quantum dot core; and forming a quantum dot shell at an outer side of the charge transition layer, wherein the charge transition layer comprises a host material and metal ions doped in the host material, wherein the metal ions are metal ions with variable charge valence states, and the charge valence states of the metal ions comprise a charge valence state of a cation in the quantum dot core and a charge valence state of a cation in the quantum dot shell.

In some examples, the manufacturing the quantum dot core comprises: dissolving a long-chain fatty acid solution containing indium ions and a long-chain fatty acid solution containing zinc ions in a non-polar solvent for reaction, so as to obtain a precursor solution, wherein a boiling point of the non-polar solvent is higher than 150 degrees Celsius; and injecting a non-polar solvent containing phosphorus compound into the precursor solution to form the quantum dot core, wherein a molar ratio of the non-polar solvent containing phosphorus compound to the long-chain fatty acid solution containing indium ions is greater than or equal to 60%.

In some examples, forming the charge transition layer at the outer side of the quantum dot core comprises: injecting a long-chain fatty acid solution containing the metal ions at the outer side of the quantum dot core; and injecting a non-polar solvent containing phosphorus compound into the long-chain fatty acid solution containing the metal ions to form the charge transition layer doped with the metal ions, wherein a molar amount of the non-polar solvent containing phosphorus compound included in the quantum dot core and the charge transition layer is a first mole, a molar amount of the long-chain fatty acid solution containing indium ions is a second mole, and the first mole is equal to the second mole.

In some examples, forming the charge transition layer at the outer side of the quantum dot core comprises: injecting a long-chain fatty acid solution doped with the metal ions and zinc ions at the outer side of the quantum dot core; and injecting a long-chain fatty acid solution containing only zinc ions into the long-chain fatty acid solution doped with the metal ions and zinc ions to form the charge transition layer doped with the metal ions, wherein a molar amount of the long-chain fatty acid solution containing indium ions included in the quantum dot core is the same as a molar amount of the long-chain fatty acid solution containing zinc ions included in the charge transition layer.

In some examples, the metal ions include at least one kind selected from the group consisting of manganese ions, iron ions, europium ions, cobalt ions and nickel ions.

In some examples, a doping mass ratio of the metal ions to the host material of the charge transition layer is less than 5%.

In some examples, the forming the quantum dot shell at the outer side of the charge transition layer comprises: injecting octanethiol and a high boiling point solution containing sulfur compound at the outer side of the charge transition layer, and heating and cooling to form the quantum dot shell, wherein a molar amount of the sulfur compound is the same as a molar amount of the long-chain fatty acid solution containing zinc ions.

At least one embodiment of the disclosure provides a quantum dot light emitting diode, wherein a light emitting layer of the quantum dot light emitting diode comprises the quantum dot according to any items as mentioned above.

At least one embodiment of the disclosure provides a display panel, wherein a light emitting region of the display panel comprises the quantum dot according to any items as mentioned above.

### BRIEF DESCRIPTION OF THE DRAWINGS

In order to clearly illustrate the technical solutions of the embodiments of the disclosure, the drawings of the embodiments will be briefly described in the following; it is obvious that the described drawings are only related to some embodiments of the disclosure and thus are not limitative to the disclosure.

FIG. 1 is a longitudinal sectional view of a quantum dot provided by an embodiment of the present disclosure;

FIG. 2 is a longitudinal sectional view of a quantum dot provided by an embodiment of the present disclosure;

FIG. 3 is a longitudinal sectional view of a quantum dot provided by an embodiment of the present disclosure;

FIG. 4 is a schematic flow chart of a manufacturing method of a quantum dot provided by an embodiment of the present disclosure;

FIG. 5 is a schematic structural diagram of a quantum dot light emitting diode provided by an embodiment of the present disclosure; and

FIG. 6 is a schematic structural diagram of a display panel provided by an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

At present, the interface between the quantum dot core and the quantum dot shell of a cadmium-free quantum dot (QD) will cause more non-radiation transitions, which will weaken the luminous ability of the QD.

In this regard, the embodiment of the present disclosure provides a novel quantum dot, and a charge transition layer is disposed between the quantum dot core and the quantum dot shell to allow the charge valence states to transition between the quantum dot core and the quantum dot shell, so as to reduce the non-radiation transitions between the interface of the quantum dot core and the interface of the quantum dot shell, thereby enhancing the luminous ability of the quantum dot.

Specific implementations of the quantum dot, the manufacturing method thereof, the QLED and the display panel provided by the embodiments of the present disclosure will be described in detail with reference to the accompanying drawings. The thickness and shape of each film layer in the accompanying drawings do not indicate the true scale, and are intended only to illustratively describe the present disclosure.

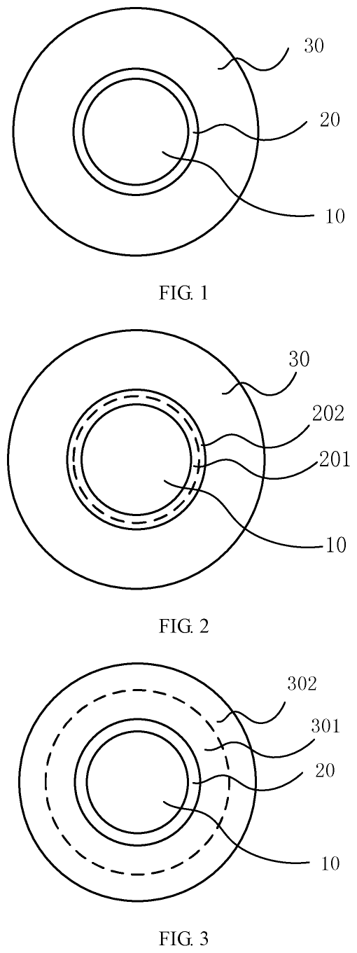

Referring to FIG. 1, an embodiment of the present disclosure provides a quantum dot. The quantum dot includes a quantum dot core 10, a charge transition layer 20 coating the quantum dot core, and a quantum dot shell 30 coating the charge transition layer 20. The charge transition layer 20 is configured to allow the charge valence states to transition between the quantum dot core 10 and the quantum dot shell 30. For example, the host material of the charge transition layer 20 is doped with metal ions, the metal ions are metal ions with variable charge valence states, and the charge valence states of the metal ions includes the charge valence state of cations in the quantum dot core and the charge valence state of cations in the quantum dot shell.

In a possible embodiment, the metal ions doped in the charge transition layer 20 can be monovalent/divalent variable valence metal ions, or divalent/trivalent variable valence metal ions, or trivalent/tetravalent variable valence metal ions.

For example, in the embodiment of the present disclosure, the material of the quantum dot core 10 can be indium phosphide (InP), and the material of the quantum dot shell 30 can be zinc sulfide (ZnS). Considering the charge valence states of phosphorus in the quantum dot core and sulfur in the quantum dot shell (or the charge valence states of indium in the quantum dot core and zinc in the quantum dot shell), the metal ions doped in the charge transition layer 20 can be divalent/trivalent variable valence metal ions, such as manganese ions, iron ions, europium ions, cobalt ions, or nickel ions, etc. For another example, the metal ions can be at least two kinds selected from the group consisting of manganese ions, iron ions, europium ions, cobalt ions and nickel ions, and the charge valence states of the main metal ions are all matched with the charge valence states of the quantum dot core or the quantum dot shell, that is, the same or similar to the charge valence states of the quantum dot core or the quantum dot shell.

The host material of the charge transition layer 20 can be the same as the material of the quantum dot core 10. For example, the host material of the charge transition layer 20 can be indium phosphide as described above. Alternatively, the host material of the charge transition layer 20 can be the same as the material of the quantum dot shell 30. For example, the host material of the charge transition layer 20 can be zinc sulfide as described above. Alternatively, the host material of the charge transition layer 20 can be other materials different from the materials of the quantum dot core 10 and the quantum dot shell 30.

If the metal ions doped in the charge transition layer 20 can emit light, the luminescence of the quantum dot may be affected. For example, if the metal ions doped in the charge transition layer 20 are europium ions, the europium ions will emit red light, and if the europium ions are doped in a green quantum dot or a blue quantum dot, the luminescence of the green quantum dot or the blue quantum dot may be affected. In order to reduce the influence of the metal ions on the luminescence of the quantum dot, the charge transition layer 20 is doped with as few metal ions as possible. For example, the doping amount (mass ratio) of the metal ions in the host material of the charge transition layer 20 in the embodiment of the present disclosure is less than 5%. In some examples, the charge transition layer 20 in the embodiment of the present disclosure is as thin as possible, so that the charge transition layer 20 is doped with as few metal ions as possible. For example, the thickness of the charge transition layer 20 in the embodiment of the present disclosure lies in the thickness range of 1 to 10 atomic layers.

In some examples, the charge transition layer 20 can include at least two layers. For example, referring to FIG. 2, the charge transition layer 20 can include a first charge transition layer 201 and a second charge transition layer 202. As shown in FIG. 2, the boundary between the first charge transition layer 201 and the second transition layer 202 is illustrated by a dashed line. In this case, the host material of the first charge transition layer 201 is the same as the material of the quantum dot core 10, and the host material of the second charge transition layer 202 is the same as the host material of the first charge transition layer 201, or the host material of the second charge transition layer 202 is the same as the material of the quantum dot shell 30.

The quantum dot shell 30 can also include at least two layers. For example, referring to FIG. 3, the quantum dot shell 30 includes a first quantum dot shell 301 and a second quantum dot shell 302. In FIG. 3, the boundary between the first quantum dot shell 301 and the second quantum dot shell 302 is illustrated by a dashed line. The first quantum dot shell 301 coats the quantum dot core 10, and the second quantum dot shell 302 coats the first quantum dot shell 301. The lattice mismatching between the first quantum dot shell 301 and the quantum dot core 10 is less than the lattice mismatching between the second quantum dot shell 302 and the quantum dot core 10. In this way, the first quantum dot shell 301 also plays a part in transitioning charge between the quantum dot core 10 and the second quantum dot shell 302, so as to reduce the non-radiation transitions from the quantum dot core 10 to the second quantum dot shell 302 and enhance the luminous ability of the quantum dot.

For example, the material of the first quantum dot shell 301 can be zinc selenide (ZnSe), and the material of the second quantum dot shell 302 can be zinc sulfide.

It should be noted that FIG. 3 takes that the charge transition layer 20 includes one layer as an example, and in the structure shown in FIG. 3, the charge transition layer 20 can also be a multi-layer structure.

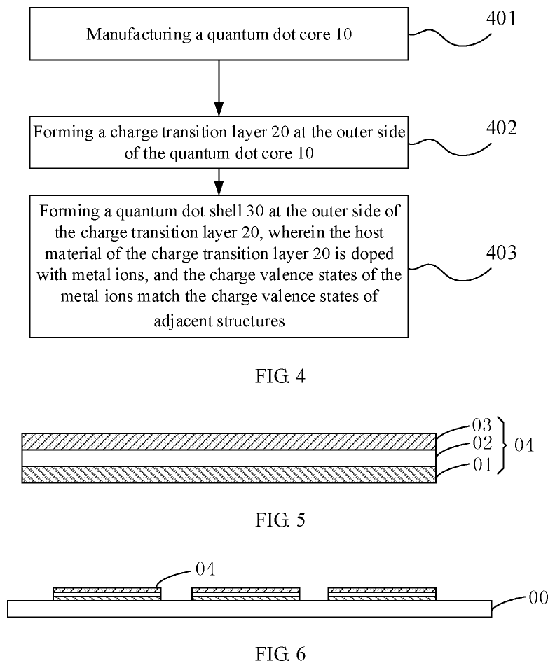

A quantum dot is provided as above, and a manufacturing method of the quantum dot provided based on the same inventive concept is described below. Referring to FIG. 4, some exemplary manufacturing processes are as follows.

S401, manufacturing a quantum dot core 10;

S402, forming a charge transition layer 20 at the outer side of the quantum dot core 10;

S403: forming a quantum dot shell 30 at the outer side of the charge transition layer 20. The host material of the charge transition layer 20 is doped with metal ions, the metal ions are metal ions with variable charge valence states, and the charge valence states of the metal ions includes the charge valence state of cations in the quantum dot core and the charge valence state of cations in the quantum dot shell.

For example, when manufacturing the quantum dot core 10, firstly, a long-chain fatty acid solution containing indium ions and a long-chain fatty acid solution containing zinc ions can be dissolved in a non-polar solvent, and be heated to cause reaction between the long-chain fatty acid solution containing indium ions and the long-chain fatty acid solution containing zinc ions, so as to obtain a precursor solution; and then, a non-polar solvent containing phosphorus compound is injected into the precursor solution to form the quantum dot core 10.

The long-chain fatty acid solution containing indium ions can be considered as a solution obtained by dissolving indium source in fatty acid. For example, the indium source can be indium chloride or indium oxide. The fatty acid can be oleic acid, which is used as the ligand of indium source, thus improving the reaction rate of indium source. For example, the long-chain fatty acid solution containing indium ions can be indium oleate. Similarly, the long-chain fatty acid solution containing zinc ions can be considered as a solution obtained by dissolving zinc source in fatty acid. For example, the zinc source can be zinc chloride or zinc oxide. The fatty acid can be oleic acid, which is used as the ligand of zinc source, thus improving the reaction rate of zinc source. For example, the long-chain fatty acid solution containing zinc ions can be zinc oleate. The non-polar solvent containing phosphorus compound can be considered to be formed by dissolving phosphorus source in non-polar solvent. The phosphorus source can be trimethylsilyl phosphorus P(TMS)_3. Here, the non-polar solvent can be a non-polar solvent with a high boiling point, such as a non-polar solvent with a boiling point higher than 150 degrees Celsius. For example, the non-polar solvent can be octadecene solution, which promotes the decomposition of phosphorus source, accelerates the formation of the quantum dot core 10, and improves the uniformity of quantum dots in particle size.

When manufacturing the quantum dot core 10, the molar ratio of the non-polar solvent containing phosphorus compound to the long-chain fatty acid solution containing indium ions is greater than or equal to 60%. Exemplarily, in the embodiment of the present disclosure, 0.1 mmol indium oleate and 0.1 mmol zinc oleate can be added into octadecene solution, and be heated to 250˜280 degrees Celsius to react under the environment of keeping water and oxygen removed and maintaining nitrogen atmosphere, so that the precursor solution can be obtained. Then, octadecene solution containing 0.08 mmol P(TMS)_3 can be injected into the precursor solution to form the quantum dot core 10.

After the quantum dot core 10 is formed, the charge transition layer 20 can be manufactured at the outer side of the quantum dot core 10. According to the difference in the host material of the charge transition layer 20, the process of manufacturing the charge transition layer 20 can be different.

In the first case, if the host material of the charge transition layer 20 is the same as the material of the quantum dot core 10, when manufacturing the charge transition layer 20, a long-chain fatty acid solution containing metal ions can be firstly injected at the outer side of the quantum dot core, and then a non-polar solvent containing phosphorus ions can be injected into the long-chain fatty acid solution containing the metal ions to form the charge transition layer 20 doped with the metal ions.

The metal ions can be at least one kind selected from the group consisting of manganese ions, iron ions, europium ions, cobalt ions and nickel ion as described above. And the metal ions are manganese ions as an example in the following description. The long-chain fatty acid solution containing metal ions can be manganese oleate. The non-polar solvent containing phosphorus compound is octadecene solution containing P(TMS)_3 as described above, so that the host material of the charge transition layer 20 is the same as the material of the quantum dot core 10.

In addition, the molar amount of the non-polar solvent containing phosphorus compound included in the quantum dot core 10 and the charge transition layer 20 is a first mole, the molar amount of the long-chain fatty acid solution containing indium ions is a second mole, and the first mole is equal to the second mole. That is, the host material of the charge transition layer 20 is the same as the material of the quantum dot core 10, but it is necessary to ensure the balance between the amount of indium and the amount of phosphorus.

Exemplarily, when manufacturing the charge transition layer 20, 0.001 mmol manganese oleate can be injected at the outer side of the quantum dot core 10, and then octadecene solution containing 0.02 mmol P(TMS)_3 can be injected, so as to form the charge transition layer 20 doped with manganese ions. When manufacturing the quantum dot core 10, the temperature is kept in the range of 250˜280 degrees Celsius, and then manganese oleate and octadecene solution containing P(TMS)_3 are injected. Because manganese oleate and octadecene solution containing P(TMS)_3 are not in the heating equipment, the temperature will decrease after injecting manganese oleate and octadecene solution containing P(TMS)_3 at the outer side of the quantum dot core 10, and for example, the temperature may be in the range of 220˜250 degrees Celsius. Because manganese ions can emit light, in order to reduce the influence of manganese ions on the luminescence of the quantum dot, the doping concentration (mass ratio) of manganese ions in the charge transition layer 20 is less than 5%. In a possible embodiment, the thickness of the charge transition layer 20 lies in the thickness range of 1-10 atomic layers.

In the second case, if the host material of the charge transition layer 20 is the same as the material of the quantum dot shell 30, when manufacturing the charge transition layer 20, a long-chain fatty acid solution containing the metal ions and zinc ions can be firstly injected at the outer side of the quantum dot core, and then a non-polar solvent containing sulfur source or selenium source can be injected to form the charge transition layer 20 doped with the metal ions.

Different from the first case, the long-chain fatty acid solution containing the metal ions and zinc ions can be zinc oleate doped with manganese compound. After the zinc oleate reacts with the non-polar solvent containing sulfur compound, that is, with the octadecene solution containing P(TMS)_3, a long-chain fatty acid solution containing only zinc ions, that is, pure zinc oleate, is injected for reaction, so that the host material of the charge transition layer 20 is the same as the material of the quantum dot shell 30. Similarly, in order to ensure the balance between the amount of indium and the amount of phosphorus, the molar amount of the long-chain fatty acid solution containing indium ions for forming the quantum dot core 10 is the same as the molar amount of the long-chain fatty acid solution containing zinc ions for forming the charge transition layer.

Exemplarily, when fabricating the charge transition layer 20, 0.02 mmol zinc oleate containing manganese compound can be injected at the outer side of the quantum dot core 10, and then 0.08 mmol of zinc oleate can be injected to form the charge transition layer 20 doped with manganese ions. Similar to the first case, the doping concentration (mass ratio) of manganese ions in the charge transition layer 20 is less than 5%, and for example, the doping concentration (mass ratio) of manganese ions in the charge transition layer 20 is 3%. In a possible embodiment, the thickness of the charge transition layer 20 lies in the thickness range of 1-10 atomic layers.

After the charge transition layer 20 is manufactured, the quantum dot shell 30 is subsequently manufactured at the outer side of the charge transition layer 20. For example, in the embodiment of the present disclosure, a ligand and a high boiling point solution containing sulfur compound can be injected at the outer side of the charge transition layer 20. For example, a non-polar solution containing sulfur compound is injected at the outer side of the charge transition layer 20, and octanethiol is used as the ligand, and after being heated and then cooled, the quantum dot shell 30 is formed. For example, the molar amount of the non-polar solution containing sulfur compound is the same as the molar amount of the long-chain fatty acid solution containing zinc ions.

Exemplarily, 1 mmol octadecene solution of tributylphosphine-sulfur adduct (S-TBP) is injected at the outer side of the charge transition layer 20, and 1.2 mL 1-octanethiol is added. Thereafter, heating is performed, the temperature is heated to about 300 degrees Celsius, and the heating time is, for example, about 120 min, so that the octadecene solution containing S-TBP reacts with 1-octanethiol to obtain the quantum dot shell 30. Here, S-TBP can be obtained by dissolving 1 mmol sulfur powder and 1.25 mL TBP in 1.25 mL 1-octadecene (ODE) solution.

In a possible embodiment, the quantum dot shell 30 can be manufactured into multiple layers, such as the first quantum dot shell 301 and the second quantum dot shell 302 described above. For example, when manufacturing the quantum dot shell 30, the first quantum dot shell 301 can be manufactured first and then the second quantum dot shell 302 can be manufactured. For example, a first mole non-polar solution containing selenium compound and octanethiol are injected at the outer side of the charge transition layer 20, and after being heated and then cooled, the first quantum dot shell 301 is formed. A second mole non-polar solution containing sulfur compound and octanethiol are injected at the outer side of the first quantum dot shell 301, and after being heated and then cooled, the second quantum dot shell 302 is formed. For example, the sum of the first mole and the second mole is the same as the molar amount of the long-chain fatty acid solution containing zinc ions.

Exemplarily, 0.5 mmol octadecene solution of Se-TBP is injected at the outer side of the charge transition layer 20, and 0.5 mL 1-octanethiol is injected. The temperature is heated to about 300 degrees Celsius, and the heating time is, for example, about 120 min, so that the octadecene solution containing Se-TBP reacts with 1-octanethiol to obtain the first quantum dot shell 301. Then the present structure is cooled to room temperature. 0.5 mmol octadecene solution containing S-TBP is injected at the outer side of the first quantum dot shell 301, and 0.5 mL 1-octanethiol is injected. The temperature is heated to about 300 degrees Celsius, and the heating time is, for example, about 120 min, so that the octadecene solution containing S-TBP reacts with 1-octanethiol to obtain the second quantum dot shell 302. For example, Se-TBP can be obtained by dissolving 1 mmol selenium powder and 1.25 mL TBP in 1.25 mL ODE solution.

After the quantum dot is obtained, it can be washed alternately with ethyl acetate and toluene for 3-4 times to obtain a purified quantum dot for later use. For example, a quantum dot light emitting diode or a display panel can be made based on the quantum dot.

Exemplarily, based on the same inventive concept, an embodiment of the present disclosure further provides a quantum dot light emitting diode (e.g., a quantum dot electroluminescent diode), and the light emitting layer of the quantum dot light emitting diode is prepared by the above quantum dot. As shown in FIG. 5, the quantum dot light emitting diode includes a light emitting layer 02, and a first electrode 01 and a second electrode 03 which are located on both sides of the light emitting layer 02. For example, the light emitting layer 02 can be prepared by the above-mentioned quantum dot or the light emitting layer 02 includes the above-mentioned quantum dot.

Based on the same inventive concept, an embodiment of the present disclosure further provides a display panel, and the light emitting region of the display panel includes the quantum dot. As shown in FIG. 6, the display panel includes a base substrate 00. The light emitting region of the display panel can include the quantum dot light emitting diode. Although the embodiment of FIG. 6 is described by taking that the quantum dot light emitting diode is located in the light emitting region of the display panel as an example, the embodiment of the present disclosure is not limited to this case, and the quantum dot can exist in the light emitting region of the display panel in any other form.

When manufacturing a display panel, for example, the quantum dot solution with a concentration of 20 mg/mL can be spin-coated on a thin film transistor (TFT) array substrate on which a hole injection layer and a hole transport layer have been sequentially provided, so as to form a light emitting layer. Then ZnO nanoparticles are deposited on the light emitting layer as an electron transport layer, and then an electrode is vacuum evaporated, and after being encapsulated, a display panel is obtained.

To sum up, in the embodiment of the present disclosure, a charge transition layer is disposed between the quantum dot core and the quantum dot shell, the host material of the charge transition layer is doped with metal ions, the metal ions are metal ions with variable charge valence states, and the charge valence states of the metal ions includes the charge valence state of cations in the quantum dot core and the charge valence state of cations in the quantum dot shell, which plays a role of buffering charges. Therefore, when Auger recombination occurs between the interface of the quantum dot core and the interface of the quantum dot shell, the non-radiation transition is reduced. In this way, the lattice defects caused by the defect states in the quantum dot core can be reduced in the process of electric excitation, and the luminous ability of the quantum dot can be enhanced.

What have been described above are only specific implementations of the present disclosure, and the protection scope of the present disclosure is not limited thereto.

Therefore, the protection scope of the present disclosure should be determined based on the protection scope of the claims.

1. A quantum dot, comprising: a quantum dot core, a charge transition layer coating at an outer side of the quantum dot core, and a quantum dot shell coating at an outer side of the charge transition layer,
wherein the charge transition layer comprises a host material and metal ions doped in the host material, the metal ions are metal ions with variable charge valence states, and the charge valence states of the metal ions comprise a charge valence state of a cation in the quantum dot core and a charge valence state of a cation in the quantum dot shell.

2. The quantum dot according to claim 1, wherein the metal ions are divalent/trivalent variable valence metal ions.

3. The quantum dot according to claim 2, wherein the metal ions include at least one kind selected from the group consisting of manganese ions, iron ions, europium ions, cobalt ions and nickel ions.

4. The quantum dot according to claim 1, wherein a thickness of the charge transition layer ranges from 1 to 10 atomic layers.

5. The quantum dot according to claim 1, wherein a doping mass ratio of the metal ions to the host material of the charge transition layer is less than 5%.

6. The quantum dot according to claim 1, wherein the host material of the charge transition layer is the same as a material of the quantum dot core, or the host material of the charge transition layer is the same as a material of at least a part of the quantum dot shell adjacent to the charge transition layer.

7. The quantum dot according to claim 1, wherein a material of the quantum dot core is indium phosphide.

8. The quantum dot according to claim 1, wherein the quantum dot shell comprises a first quantum dot shell coating the charge transition layer and a second quantum dot shell coating the first quantum dot shell; and a lattice mismatching between the first quantum dot shell and the quantum dot core is less than a lattice mismatching between the second quantum dot shell and the quantum dot core.

9. The quantum dot according to claim 8, wherein a material of the first quantum dot shell is zinc selenide, and a material of the second quantum dot shell is zinc sulfide.

10. A manufacturing method of a quantum dot, comprising:
manufacturing a quantum dot core;
forming a charge transition layer at an outer side of the quantum dot core; and
forming a quantum dot shell at an outer side of the charge transition layer,
wherein the charge transition layer comprises a host material and metal ions doped in the host material, wherein the metal ions are metal ions with variable charge valence states, and the charge valence states of the metal ions comprise a charge valence state of a cation in the quantum dot core and a charge valence state of a cation in the quantum dot shell.

11. The manufacturing method according to claim 10, wherein manufacturing the quantum dot core comprises:
dissolving a long-chain fatty acid solution containing indium ions and a long-chain fatty acid solution containing zinc ions in a non-polar solvent for reaction, so as to obtain a precursor solution, wherein a boiling point of the non-polar solvent is higher than 150 degrees Celsius; and
injecting a non-polar solvent containing phosphorus compound into the precursor solution to form the quantum dot core, wherein a molar ratio of the non-polar solvent containing phosphorus compound to the long-chain fatty acid solution containing indium ions is greater than or equal to 60%.

12. The manufacturing method according to claim 11, wherein forming the charge transition layer at the outer side of the quantum dot core comprises:
injecting a long-chain fatty acid solution containing the metal ions at the outer side of the quantum dot core; and
injecting a non-polar solvent containing phosphorus compound into the long-chain fatty acid solution containing the metal ions to form the charge transition layer doped with the metal ions,
wherein a molar amount of the non-polar solvent containing phosphorus compound included in the quantum dot core and the charge transition layer is a first mole, a molar amount of the long-chain fatty acid solution containing indium ions is a second mole, and the first mole is equal to the second mole.

13. The manufacturing method according to claim 11, wherein forming the charge transition layer at the outer side of the quantum dot core comprises:
injecting a long-chain fatty acid solution doped with the metal ions and zinc ions at the outer side of the quantum dot core; and
injecting a long-chain fatty acid solution containing only zinc ions into the long-chain fatty acid solution doped with the metal ions and zinc ions to form the charge transition layer doped with the metal ions,
wherein a molar amount of the long-chain fatty acid solution containing indium ions included in the quantum dot core is the same as a molar amount of the long-chain fatty acid solution containing zinc ions included in the charge transition layer.

14. The manufacturing method according to claim 11, wherein the metal ions include at least one kind selected from the group consisting of manganese ions, iron ions, europium ions, cobalt ions and nickel ions.

15. The manufacturing method according to claim 14, wherein a doping mass ratio of the metal ions to the host material of the charge transition layer is less than 5%.

16. The manufacturing method according to claim 11, wherein forming the quantum dot shell at the outer side of the charge transition layer comprises:
injecting octanethiol and a high boiling point solution containing sulfur compound at the outer side of the charge transition layer, and heating and cooling to form the quantum dot shell,
wherein a molar amount of the High boiling point solution containing sulfur compound is the same as a molar amount of the long-chain fatty acid solution containing zinc ions.

17. A quantum dot light emitting diode, wherein a light emitting layer of the quantum dot light emitting diode comprises the quantum dot according to claim 1.

18. A display panel, wherein a light emitting region of the display panel comprises the quantum dot according to claim 1.
